(19) United States
(12) Patent Application Publication
(10) Pub. No.: US 2006/0245230 A1
(43) Pub. Date: Nov. 2, 2006

(54) Memory module and method for operating a memory module

(76) Inventor: Luca de Ambroggi, Dresden (DE)

Correspondence Address: SLATER & MATSIL LLP, 17950 PRESTON ROAD, SUITE 1000, DALLAS, TX, 75252, US

(21) Appl. No.: 11/119,396

(22) Filed: Apr. 29, 2005

(51) Int. Cl. G11C 5/06

(52) U.S. Cl. 365/63

(57) ABSTRACT

A memory module comprises a nonvolatile memory unit (2) and a volatile memory unit (1), which are electrically coupled. The nonvolatile memory unit (2) is operable to store data permanently. The volatile memory unit (1) is operable to load the data stored in the nonvolatile memory unit (2) in order to perform an operation based on the data.

### TECHNICAL FIELD

The present invention generally relates to a memory module comprising a volatile memory unit and a nonvolatile memory unit and further relates to a method for operating the memory module.

### BACKGROUND

Conventional volatile memory cannot permanently store data. When the power supply goes off the memory content is lost. For operating a volatile memory, means for permanent storing of device parameters may be advantageous. An exemplary need to store such device parameters permanently is described in the following.

A volatile memory comprises a multitude of locations. Each location enables to store a small piece of information, which is a data word, a bit or byte. Each location is accessible by an individual address. The volatile memory further may comprise an area of redundant locations, e.g., for the purpose of substituting failing locations. The failing location may be blocked and be replaced with the redundant location.

If the failing location is detected it may be disabled and replaced with one of the redundant locations. If the failing location has been addressed during normal operation, memory access to the redundant location is executed instead of memory access to the respective failing location.

In this case, once the failing location is detected, a solid solution may be provided that ensures the redundant location works along with the other locations of the volatile memory without any problems. This solution should be independent from external conditions such as power supply.

For the purpose of storing some kind of data, which are, e.g., the addresses of the failing locations, means for permanent storage of information have to be provided. In conventional volatile memory, the information is written in a hardware manner into the memory.

The approach commonly used is to implement some hardware fuses. Fuses are hardware connections that can be blown away by a laser. Whether blowing away or not blowing away of one of the fuses depends on the information that is to be stored within. Fuses are used to permanently identify the failing location and the respective redundant location, which substitutes the failing location during each functional operation if the failing location itself has been addressed.

Not only defect locations but also memory blocks comprising several locations may be replaced in the same manner. In this case a memory block with a defect location is replaced with a redundant memory block.

Programming the fuses is performed during the wafer sorting phase. Subsequent changes or storing of additional information after the wafer sorting phase is impossible while using fuses. Failing locations, which are detected during normal operation of the memory, cannot be stored anymore.

During the wafer sorting phase properly detecting the failing locations and replacing with redundant locations needs some effort. A fuse implementation system providing fuses, which can be blown away, is provided on a silicon level of the chip. The fuse implementation system requires space, because the fuses have a relatively large extension compared to the space required for the memory locations.

Furthermore, the impact of the fuse implementation system on the silicon area including the memory locations cannot be neglected. This is because the laser is used to blow the fuses. Regarding quality, the blowing of fuses can incur contamination by the blown fuses or by the laser itself. The blown fuses may contaminate the silicon area resulting in further failing locations or the usage of the laser itself may result in collateral damage of the locations. A passivation layer normally covering the locations and the fuse implementation system is damaged by the laser in order to blow fuses. As a result, the protecting effect of the passivation layer is decreased.

Detecting and substituting the failing locations takes a lot of testing time, because the wafer is placed below the laser during a further step.

The wafer sorting phase is the only step where the failing locations can be substituted. Due to this, after the wafer sorting phase a memory failure cannot be repaired despite maybe being detected.

A nonvolatile memory enables to permanently store data, which then is kept for the whole life of the product. Nonvolatile memories may be realized in different ways. Examples are read-only memory (ROM), programmable read-only memory (PROM), erasable programmable read-only memory (EPROM) and electrical erasable programmable read-only memory (EEPROM).

The advantage of the ROM is the low price per device. The ROM cannot be programmed electrically. Programming occurs during one of the production steps. When the production process has been completed, the content of the ROM can no longer be changed.

The PROM is manufactured as a blank memory. After having been programmed once, the content cannot be changed anymore.

The EPROM can be programmed again after having been exposed to ultraviolet light for erasing.

The above-described nonvolatile memories cannot be electrically erased. The EEPROM can be electrically programmed and erased. It retains the stored data for a long time without power supply and can easily be programmed and erased many times.

The data can be easily electrically programmed into the EEPROM during whatever time window in the testing flow or later on. Furthermore, the programmability of the redundancy data as well as other data is achieved electrically via software. As a result, the data can be changed several times.

Flash memory is a form of EEPROM that allows multiple memory locations to be erased or written in one programming operation.

### SUMMARY OF THE INVENTION

One aspect of the invention provides a memory module comprising a volatile and a nonvolatile memory unit, which is operable to store some data permanently. The data is loaded from the nonvolatile memory unit to the volatile memory unit. The data may comprise information to operate the volatile memory module, e.g., trimming or configuration options, security information or information about failing locations. Trimming or configuration options set the volatile memory in order to achieve a better setup, e.g., in performances, reliability or other aspects. Security information is used in order to protect, e.g., against writing and/or reading operations of the whole volatile memory, or just a part of it. The security options may depend on needs and requests of the customer.

In order to store information about failing locations of the nonvolatile memory unit the nonvolatile memory unit stores a list identifying failing locations of the volatile memory unit and the locations for redundancy, which substitutes these failing locations during normal operation mode. Memory access based upon the list is executed to the substituting locations when the failing locations are addressed. The list can be downloaded to the volatile memory unit before normal operation mode in order to enable fast memory access.

In a further aspect of the invention, the data can be easily electrically programmed into the nonvolatile memory unit and can be changed during the lifetime of the memory module. Due to this great flexibility, the data in the nonvolatile memory unit can be updated once the wafer sorting phase has finished.

Omitting the fuses, which are relatively large, the area of the memory module is decreased compared to a conventional memory module. Furthermore, the testing time is reduced because the step of blowing fuses is omitted and contamination by the blown fuses or the laser itself is prevented.

An embodiment of the invention comprises a volatile memory unit and a nonvolatile memory unit, which are stacked. The volatile memory unit is, for example, a RAM and the nonvolatile memory unit is, for example, a flash or EEPROM. The nonvolatile memory unit and the volatile memory unit are electrically coupled in order to exchange data. The volatile memory unit and the nonvolatile memory unit each comprise several pads. Some of the pads of the nonvolatile memory unit are coupled to the pads of the volatile memory unit in order to exchange the data. Other pads may be coupled to contact pads, which are accessible from the outside. A handshake protocol is provided between the nonvolatile memory unit and the volatile memory unit, which loads up some volatile registers downloading them from the nonvolatile memory unit. The content that has been downloaded is then kept active in the volatile memory unit since a new power-down will occur. In such a situation the memory always has available all the information that is required for correct functionality.

For downloading the data two extra pads are provided for the nonvolatile memory unit as well as for the volatile memory unit. One pad is for a clock signal and the other pad is for a data signal. The extra pads for the clock signal are coupled as well as the extra pads for the data signal in order to permit the memory units to communicate in a serial way without any external interface.

Other protocols than the serial could be used as well, e.g., parallel ×4, ×8, etc., which means four and eight bits respectively are transmitted parallel. The use of a serial approach versus the parallel may be the results of the best compromise between the performances, which is required, and the interface area, which is required for the pads used for transmission between the nonvolatile and volatile memory unit.

### BRIEF DESCRIPTION OF THE DRAWINGS

For a more complete understanding of the present invention and the advantages thereof reference is now made to the following descriptions taken in conjunction with the accompanying drawings in which:

FIG. 1 shows a top view of a first embodiment of the memory module comprising a nonvolatile memory unit stacked on a volatile memory unit;

FIG. 2 shows a block diagram of the volatile memory unit;

FIG. 3 shows a cross-section according to FIG. 1 of the memory module;

FIG. 4 shows a cross-section of a second embodiment of the memory module;

FIG. 5 shows a cross-section of a third embodiment of the memory module;

FIG. 6 shows a cross-section of a fourth embodiment of the memory module; and

FIG. 7 shows a cross-section of a fifth embodiment of the memory module.

### DETAILED DESCRIPTION OF ILLUSTRATIVE EMBODIMENTS

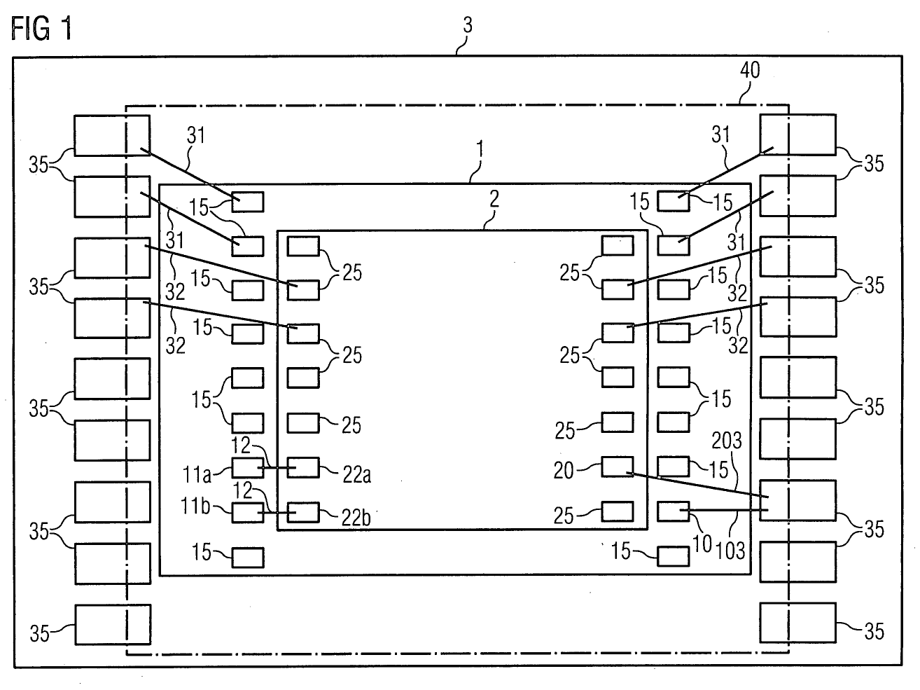

FIG. 1 shows a top view of a memory module comprising a volatile memory unit 1 and a nonvolatile memory unit 2 stacked on a base substrate 3.

The volatile memory unit 1 and the nonvolatile memory unit 2 are formed as separate structural components. The volatile memory unit 1 may be a RAM and the nonvolatile memory unit 2 may be an electrically programmable and rewritable flash. The production of the memory module is very cheap and simple because the volatile memory unit 1 and the nonvolatile memory unit 2 are fabricated separately in a conventional way before joining them together and electrically coupling them.

In this embodiment, the nonvolatile memory unit 2 is stacked on the volatile memory unit 1, while the volatile memory unit 1 is arranged on a base substrate 3. The volatile and nonvolatile memory unit 1, 2 may be arranged in reverse order. It is also possible to arrange both the volatile and the nonvolatile memory unit 1, 2 on the base substrate 3 next to each other. The configuration of the volatile and nonvolatile memory unit 1, 2 is not significant. The position of the volatile and nonvolatile memory unit 1, 2 may depend just on package issue. In order to fix these arrangements the components may be glued onto each other.

The base substrate 3 comprises contact leads 35, which are accessible, for connecting the memory module with a device and for applying signals or power supply in order to operate the memory module.

The volatile memory unit 1 and the nonvolatile memory unit 2 each comprise pads 10, 11a, 11b, 15, 20, 22a, 22b, 25 for coupling the components with each other or with the contact leads 35 of the base substrate 3. The pads 11a, 11b of the volatile memory unit 1 can be coupled directly to the pads 22a, 22b of the nonvolatile memory unit 2, for example via wire bonding as indicated by the wire connection 12. On the other hand, the pads 10 of the volatile memory unit 1 can be coupled to the pads 20 of the nonvolatile memory unit 2 without a direct wire connection by connecting the same contact lead 35. The pads 15 of the volatile memory unit 1, which are not coupled to the pads 25 of the nonvolatile memory unit 2, are coupled directly to the contact lead 35.

In the following, the pads 11a, 11b, 22a, 22b of the volatile and nonvolatile memory unit 1, 2 being coupled are so-called extra pads. The other pads 15, 25, which are normally coupled to contact leads 35, are so-called usermode pads. These usermode pads are usable in order to operate the memory module, e.g., by applying address and data signals in order to load or store data. Power supply is applied to usermode pads also.

The wire bonding 31, 32, 12, 103, 203 may be protected by a molding cap 4 or another coating.

A contour 40 of such a coating is indicated by a dashed line in FIG. 1. The coating is arranged in order to cover the pads 10, 11a, 11b, 15, 20, 22a, 22b, 25 of the nonvolatile memory unit 2 and the volatile memory unit 1 and the wire bondings 31, 32, 12, 103, 203. Portions of the contact leads 33, 35 adjacent to the connected wires are also covered. As a result both the volatile and the nonvolatile memory unit 1, 2 are accessible only by portions of contact leads 35 which are not covered.

The nonvolatile memory unit 2 is used to store information, e.g., about failing locations of the volatile memory unit 1. This information can be detected during a testing phase, which is performed before first usage of the memory module. If the nonvolatile memory unit 2 is electrically rewritable the information can be updated during normal operation once a failing location has been detected or after performing a test routine.

A principle implementation of data exchange between the volatile and the nonvolatile memory unit 1, 2 is described in the following.

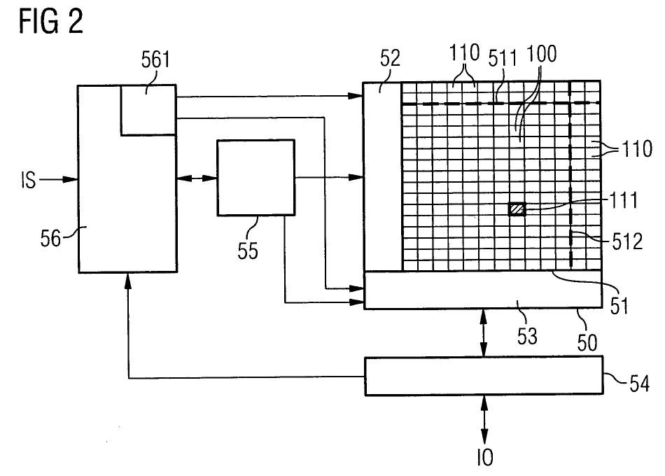

FIG. 2 shows a block diagram of the volatile memory unit 1. The volatile memory unit 1 comprises a control logic 56 with an address decoder 561. A generic voltage generator 55 for power supply is coupled to the control logic 56 and a memory block 50. The volatile memory unit 1 further comprises an input/output buffer and latches 54 coupled to the control logic 56 and to the memory block 50. The memory block 50 comprises a memory array 51, an x-decoder and y-decoder both coupled to the address decoder 561. During operation the volatile memory unit 1 is controlled by input signals IS applied to the control logic 56. Data input and output signals 10 are applied at the input/output buffer and latches 54.

The nonvolatile memory unit 2 may comprise similar components.

The memory array 51 comprises locations 100, which are arranged in columns and rows, to store small piece of data, e.g., a bit, a byte or a word. Each location 100 is accessible by an address. The address decoder 561 identifies the location 100 belonging to the respective address, which is applied as an input signal IS to the control logic 56, and executes memory access to the location 100. For performing memory access the x-decoder 52 activates the respective row of the location 100 and the y-decoder 53 activates the respective column of the location 100.

Some of the locations 100 of the volatile memory unit 1 may be defective. The memory array 51 includes a first redundant area 551 and a second redundant area 552 comprising a multitude of residual locations 110 for substituting defect locations 111. The first and second redundant areas 511, 512 are arranged as redundant rows and columns, respectively. Alternatively the redundant area may be arranged as sector of the memory array 51. In case of memory access during normal operation the address decoder 561 of the volatile memory unit 1 executes memory access to the residual location 110 instead of the failing location 111 if the failing location 111 is addressed.

Failing locations 111 can be detected during a test flow or the lifetime of the device even in the application whenever the architecture of the device permits these features. A list identifying the failing locations 111 and the respective substituting residual locations 110 is stored in the nonvolatile memory unit 2. If power on occurs, the list of the failing locations 111 is downloaded into the volatile memory unit 1. A handshake protocol is provided to transmit data from the nonvolatile memory unit 2 to the volatile memory unit 1.

The address decoder 561 substitutes the residual locations 110 for the failing locations 111 based upon the list.

The nonvolatile memory unit 2 is not restricted to store information about the failing locations 111. Furthermore, it can be used to store trimming options, for example information about the volatile memory unit 1 behavior or for a better regulation of the supply circuit. Security features can also be stored in the nonvolatile memory unit 2. For these purposes the memory module may provide a security comment to protect the whole volatile memory or special locations. For example, after the customer has performed this security command, these locations cannot be rewritten again. Protection could be ensured reading access as well to the whole volatile memory or special locations. The nonvolatile memory unit 2 stores information indicating that the security command has been performed and the data content of the respected locations. The data content is downloaded to the volatile memory unit 1 in combination with information not to rewrite or read the data content.

In order to download data from the nonvolatile memory unit 2 to the volatile memory unit 1, two extra pads 11a, 11b are provided for the volatile memory unit 1 and two extra pads 22a, 22b are provided for the nonvolatile memory unit 2, as shown in FIG. 1. The extra pads 11a, 11b, 22a, 22b comprise data signal pads 11a, 22a arranged on the volatile memory unit 1 and the nonvolatile memory unit 2, respectively. These data signal pads 11a, 22a are coupled in order to transmit a data signal. The extra pads further comprise clock signal pads 11b, 22b arranged on the volatile memory unit 1 and on the nonvolatile memory unit 2, which are connected in order to transmit a clock signal. As a result a serial communication way synchronized by the clock signal is provided. The clock signal can be provided either by the volatile or nonvolatile memory unit 1, 2, even if the data signal is not provided by the same component. Downloading is performed in order to a standard user mode protocol. Alternatively, more than one pair of data pads may be provided resulting in a parallel communication.

Alternatively, an external clock signal is applied to the contact lead 35, which is coupled to a pad 10, 20 of the volatile and nonvolatile memory units 1, 2.

The downloaded content is kept active in the volatile memory module 1 since a power down occurs.

Downloading data from the nonvolatile memory unit 2 to the volatile memory unit 1 can be performed after switching the power supply or after performing a reset. Downloading may be also performed during normal operation mode.

Transmitting data from the volatile memory 1 to the nonvolatile memory 2 can be performed during normal operation mode in order to update some data or before shut down in order to save actual trimming options.

Executing memory access by the volatile memory unit 1 to the data content stored in the nonvolatile memory unit 2 or by the nonvolatile memory unit 2 to the data content stored in the volatile memory unit 1 without downloading is also possible.

Other handshake solutions for data transmission between the volatile and nonvolatile memory units 1, 2 can be considered also. They may depend on the architecture or on the application of the memory module.

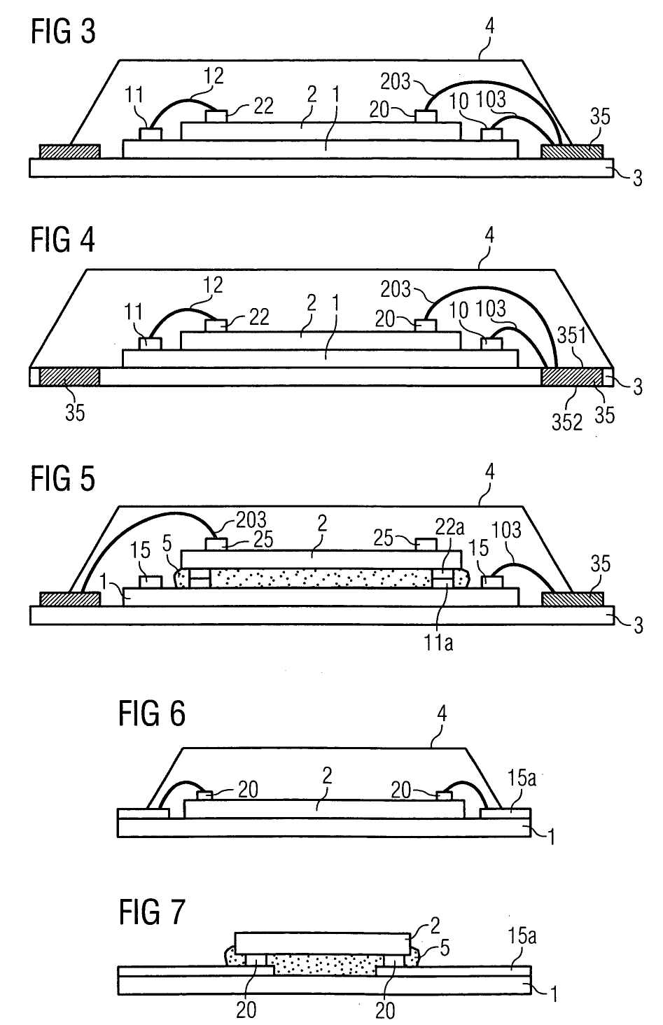

The following FIGS. 3 to 7 show further embodiments of the invention. The differences mostly consider the arrangement of the volatile and nonvolatile memory units 1, 2 and their electrical coupling.

FIG. 3 shows a cross-section of the memory module according to FIG. 1. The volatile memory unit 1 is stacked on a base substrate 3 comprising contact leads 35 on its surface.

Each of the volatile memory unit 1 and the nonvolatile memory unit 2 comprise several pads 11, 22, 10, 20. In order to transmit data between the volatile memory unit 1 and the nonvolatile memory unit 2, some of these pads 11, 22 are connected by wire bonding 12 directly. Another pad 10 of the volatile memory unit 1 is coupled to another pad 20 of the nonvolatile memory unit 2 by connecting these pads 10, 20 to the same contact pad 35 by wire bonding 103, 203. The substrate 3 with the stacked volatile and nonvolatile memory unit 1, 2 is covered by a cap 4 in order to protect the wire bondings 12, 103, 203 and the volatile and nonvolatile memory units 1, 2. The cap is formed to cover the wire bondings 12, 103, 203 while leaving portions of the contact leads 35 accessible.

FIG. 4 shows another embodiment, which differs from FIG. 3 in the form of the contact leads 35 and the cap 4. The contact leads 35 are through connections that are accessible from their bottom surface 352. A top surface 351 of the through connections 35 is coupled to the pads 10, 20 of the volatile and nonvolatile memory units 1, 2 by wire bondings 103, 203. The cap 4 covers the total top surface of the base substrate 3 including the wire bondings 12, 102, 203, the top surface 351 of the through connections 35 and the volatile and nonvolatile memory units 1, 2.

FIG. 5 shows a further embodiment of a memory module comprising the base substrate 3, the volatile memory unit 1 and the nonvolatile memory unit 2, which are stacked. The extra pads 11a of the volatile memory unit 1 and the extra pads 22a of the nonvolatile memory unit 2 are arranged on top of each other. They are connected by so-called flip-chip coupling. Glue 5 is inserted between the volatile memory unit 1 and the nonvolatile memory unit 2 for fixing and protecting.

Further pads of the volatile memory unit 1 or the nonvolatile memory unit 2 are provided in order to be connected to the contact pads 35 of the base substrate 3. The volatile memory unit 1 comprises further pads 15, 25 as well as the nonvolatile memory unit 2. The pads 25 of the nonvolatile memory unit 2 are on a top surface of the nonvolatile memory module 2, while the pads, which are coupled by the flip-chip method, are on a bottom surface of the nonvolatile memory unit 2. The pads 15 on the top surface are connected to the contact leads 35 by wire bonding. It is also possible to connect these pads to pads of the nonvolatile memory unit 2 by wire bonding in order to provide further direct connections between the volatile and nonvolatile memory units 1, 2 besides the flip-chip connections.

The contact leads 35 are arranged on the base substrate 3. The volatile and nonvolatile memory units 1, 2, the wire bondings 103, 203 and portions of the contact leads 35 are covered by the cap 4 similar to FIG. 3.

It is also possible that only one of the volatile memory unit 1 or the nonvolatile memory unit 2 is connected to the contact leads 35 of the memory module. The one of the volatile memory unit 1 or the nonvolatile memory unit 2, which is not connected to the contact leads 35 may comprise just the extra pads.

The connection of the contact leads 35 and the pads of the volatile memory module 1 or the nonvolatile memory module 2 does not need to be a wire bonding. A flip-chip connection or another form of connection is also possible.

The following embodiments of the invention do not comprise a base substrate 3.

FIG. 6 shows an embodiment comprising the volatile memory module 1 and the nonvolatile memory module 2, which is stacked. The pads 15a of the volatile memory unit 1 are formed in order to serve as contact leads having a larger extension. This means the pads 15a of the volatile memory unit 1 are coupled to the pads 20 of the nonvolatile memory unit 2. The cap 4 covers the wire bonding and portions of the pads 15a of the volatile memory unit 1.

FIG. 7 shows a further embodiment comprising a volatile memory module 1 having pads 15a formed in order to serve as contact leads also. The nonvolatile memory unit 2 is stacked in order to connect its pads 20 with the pads 15a of the volatile memory module 1 by a flip-chip connection. Glue 5 is arranged between the volatile and nonvolatile memory units 1, 2. This embodiment does not have a cap 4 because the glue 5 fixes and protects the connections.

A volatile memory unit 1 having pads 15 serving as contact leads may be provided with further pads that are not used as contact leads. These extra pads are connected to the nonvolatile memory unit also.

The nonvolatile memory unit may comprise pads serving as contact leads also.

The invention also covers any combination of the features shown in FIGS. 1 to 7.

What is claimed is:

1. A memory module comprising:
a nonvolatile memory unit operable to store data permanently; and
a volatile memory unit being affixed to the nonvolatile memory unit and being electrically coupled to the nonvolatile memory unit, the volatile memory unit being operable to load the data stored in the nonvolatile memory unit.

2. The memory module in accordance with claim 1, wherein:
the volatile memory unit is operable to perform at least one operation based on a data set;
the nonvolatile memory unit is operable to store the data set; and
the memory module is operable to load the data set from the nonvolatile memory unit to the volatile memory unit.

3. The memory module in accordance with claim 1, wherein the nonvolatile memory unit is electrically erasable and electrically rewritable.

4. The memory module in accordance with claim 1, wherein the volatile memory unit comprises a first semiconductor chip and wherein the nonvolatile memory unit comprises a second semiconductor chip.

5. The memory module in accordance with claim 1, wherein the volatile memory unit comprises a data signal pad and wherein the nonvolatile memory unit comprises a data signal pad that is coupled to the data signal pad of the volatile memory unit.

6. The memory module in accordance with claim 5, wherein the nonvolatile memory unit provides a data signal at the data signal pads of the volatile and nonvolatile memory units or wherein the volatile memory unit provides a data signal at the data signal pads of the volatile and nonvolatile memory units.

7. The memory module in accordance with claim 5, wherein the data signal pads of the volatile and nonvolatile memory unit are coupled by wire bonding.

8. The memory module in accordance with claim 5, wherein the data signal pads of the volatile and nonvolatile memory unit are coupled by flip-chip bonding.

9. The memory module in accordance with claim 1, wherein the volatile memory unit comprises a clock signal pad and wherein the nonvolatile memory unit comprises a clock signal pad that is coupled to the clock signal pad of the volatile memory unit.

10. The memory module in accordance with claim 9, wherein an external clock signal is applied to the clock signal pad of the nonvolatile memory unit and to the clock signal pad of the volatile memory unit.

11. The memory module in accordance with claim 9, wherein the clock signal pads of the volatile and nonvolatile memory unit are coupled by wire bonding.

12. The memory module in accordance with claim 9, wherein the clock signal pads of the volatile and nonvolatile memory unit are coupled by flip-chip bonding.

13. A memory module comprising:
a volatile memory unit comprising at least a first location and at least a second location, the first location and the second location each operable to store an amount of data;
a memory configuration table being adaptable to contain a list identifying the first location and the second location;
means for executing a memory access based upon the list in the memory configuration table to the second location instead of the first location when the first location is addressed; and
a nonvolatile memory unit being electrically coupled to the volatile memory unit, the nonvolatile memory unit operable to store the list;
wherein the memory module is operable to load the list from the nonvolatile memory unit to the volatile memory unit.

14. The memory module of claim 13, wherein the means for executing is disposed within the volatile memory unit.

15. The memory module of claim 13, wherein the memory configuration table is stored in the nonvolatile memory unit, the list being stored in the memory configuration table.

16. A memory module comprising:
a first semiconductor chip having a first surface, the first semiconductor chip comprising a volatile memory; and
a second semiconductor chip having a first surface mounted on the first surface of the first semiconductor chip, the second semiconductor chip being electrically coupled to the first semiconductor chip, the second semiconductor chip comprising a nonvolatile memory.

17. The memory module of claim 16, further comprising a base substrate having an upper surface, a second surface of the first semiconductor chip being mounted on the upper surface of the base substrate.

18. The memory module of claim 17, wherein the first semiconductor chip is wire bonded to the base substrate and wherein the second semiconductor chip is wire bonded to the base substrate.

19. The memory module of claim 17, wherein the first semiconductor chip is wire bonded to the second semiconductor chip.

20. The memory module of claim 16, wherein the pads of the first semiconductor chip are flip-chip bonded to pads of the second semiconductor chip.

21. The memory module of claim 16, wherein the nonvolatile memory stores operating configuration information that is used by the volatile memory.

22. The memory module of claim 21, wherein the operating configuration information comprises address redundancy information.

23. A method to operate a memory module comprising a volatile and a nonvolatile memory unit that are electrically coupled, the method comprising:
storing data in the nonvolatile memory unit;
transmitting the data from the nonvolatile memory unit to the volatile memory unit; and
performing an operation based on the transmitted data in the volatile memory unit.

24. The method of claim 23, wherein the data comprises trimming or security data.

25. The method of claim 24, wherein the data comprises security data that is used to protect at least part of the volatile memory unit against reading and/or writing operations.

26. The method of claim 23, wherein transmitting comprises:
establishing a first connection between the volatile and nonvolatile memory unit;
establishing a second connection between the volatile and nonvolatile memory unit;
providing a clock signal by the volatile memory unit or the nonvolatile memory unit;
providing a data signal by the volatile memory unit or the nonvolatile memory unit;
transmitting the clock signal via the first connection; and
transmitting the data signal via the second connection, the data signal being synchronized with the clock signal.

27. The method of claim 26, wherein the clock signal and the data signal are provided by the volatile memory unit or the nonvolatile memory unit.

28. The method of claim 23, wherein the data stored in the nonvolatile memory unit comprises a list identifying a first and a second location in the volatile memory unit, and wherein performing an operation comprises executing a memory access to the second location instead of the first location when the first location is addressed.

29. The method of claim 28, wherein the list is loaded from the nonvolatile memory unit to the volatile memory unit before executing memory access.
